(19) United States
(12) Patent Application Publication
(10) Pub. No.: US 2024/0421800 A1
(43) Pub. Date: Dec. 19, 2024

(54) METHODS AND APPARATUS FOR KALMAN FILTER ERROR RECOVERY THROUGH Q- BOOSTING ALONG OBSERVATION SUB-SPACES

(71) Applicant: Torc Robotics, Inc., Blacksburg, VA (US)

(72) Inventors: Vicent Rodrigo Marco, Stuttgart (DE); Joseph R. Fox-Rabinovitz, Austin, TX (US)

(21) Appl. No.: 18/741,613

(22) Filed: Jun. 12, 2024

Related U.S. Application Data
(60) Provisional application No. 63/508,786, filed on Jun. 16, 2023.

(51) Int. Cl. H03H 17/02; G06F 17/16

(52) U.S. Cl. CPC H03H 17/0257; G06F 17/16

(57) ABSTRACT

An autonomous vehicle including a Kalman filter error recovery system is disclosed. The Kalman filter error recovery system includes at least one processor and at least one memory storing instructions, which, when executed by the at least one processor, cause the Kalman filter error recovery system to perform operations including increasing eigenvalues of a covariance matrix to adjust probability distribution of a state vector error due to unmodelled process noise in measurements from one or more position sensors, and returning the state covariance to a diagonal state to perform a dynamic covariance reset.

### CROSS-REFERENCE TO RELATED APPLICATION

This application claims priority to and the benefit of U.S. Provisional Patent Application Ser. No. 63/508,786, entitled “METHODS AND APPARATUS FOR KALMAN FILTER ERROR RECOVERY THROUGH Q-BOOSTING ALONG OBSERVATION SUB-SPACES,” filed Jun. 16, 2023, and the content of which is incorporated herein in its entirety for all purposes.

### TECHNICAL FIELD

The field of the disclosure relates to methods and apparatus for recovery of Kalman Filters equipped with outlier rejection mechanisms through Q-boosting restricted to the sub-spaces of individual observations with and without covariance reset.

### BACKGROUND

Autonomous vehicles employ fundamental technologies such as, perception, localization, behaviors and planning, and control. Perception technologies enable an autonomous vehicle to sense and process its environment. Perception technologies process a sensed environment to identify and classify objects, or groups of objects, in the environment, for example, pedestrians, vehicles, or debris. Localization technologies determine, based on the sensed environment, for example, where in the world, or on a map, the autonomous vehicle is. Localization technologies process features in the sensed environment to correlate, or register, those features to known features on a map. Localization technologies may rely on inertial navigation system (INS) data. Behaviors and planning technologies determine how to move through the sensed environment to reach a planned destination. Behaviors and planning technologies process data representing the sensed environment and localization or mapping data to plan maneuvers and routes to reach the planned destination for execution by a controller or a control module. Controller technologies use control theory to determine how to translate desired behaviors and trajectories into actions undertaken by the vehicle through its dynamic mechanical components. This includes steering, braking and acceleration.

Various versions of the Kalman filter (e.g., extended, unscented) have seen widespread usage throughout the field of state estimation since its inception in localization technologies, and especially in the area of a global navigation satellite system (GNSS) based navigation. The original goal of the filter was to simplify the computation and tuning of the estimation algorithm. The filter's popularity is a testament to how successfully that goal was met. Alternative state estimation methods such as factor graph approaches can yield more accurate results but come with the cost of significant additional computation load and more complex setup. Another reason for the ubiquity of Kalman Filters is the body of work done on their analysis and characterization.

In the GNSS-based navigation, Kalman filtering is generally used to avoid long-term error accumulations from error sources like noise, bias, scale factor errors, misalignments, temperature dependencies, and gyro g-sensitivity, etc. Without error rejection, a Kalman filter may temporarily enter a bad state, but which will be recoverable. While outlier rejection mechanisms are commonly used to prevent unmodeled measurement errors from corrupting the estimates of Kalman filters, however, the combination of an outlier rejection mechanism with, biased state estimates and overoptimistic Kalman filter state uncertainty, may result in an unrecoverable situation. Accordingly, in some applications, it is a broad practice to combine outlier rejection techniques with recovery strategies to increase the uncertainty of the state estimates. Currently known recovery techniques for outlier rejection, for example, outlier rejection of a position signal being fused into extended Kalman filtering is Q-boosting and returning the state covariance to its initial form usually by diagonalizing the matrix and referred herein as a naïve covariance reset. Q-boosting is an expansion of the state covariance matrix, which compensates for unaccounted process noise that is conventionally denoted by Q. The GNSS-based navigation may also be referred as an inertial navigation system based (INS-based) navigation, which uses an inertial measurement unit (IMU) and a global navigation satellite system (GNSS) receiver.

Both of the Q-boosting and naïve covariance reset techniques for outlier rejection have certain drawbacks or deficiencies in some typical scenarios. For example, when the state covariance is not diagonal in its own reference frame, for example, when the position covariance ellipsoid is approximately aligned to north, cast, down (NED) from repeated GNSS measurements while the state is in earth-centered, earth-fixed (ECEF) coordinates, the naïve covariance reset technique (or algorithm) initially decreases the largest eigenvalue of the state covariance and extends the recovery procedure. In other words, in the naïve covariance reset algorithm, the return of the covariance matrix to a diagonal form and ostensible boosting of eigenvalues may cause problems with Q-boosting because of the improper handling of the rotation of the covariance eigenspace.

Additionally, some sensors (or pseudo-sensors) may measure an incomplete subset of the available dimensions, such as a map localizer pseudo-sensor measures in north east directions of NED, a barometer sensor measuring in down direction of NED, wheel speed sensors measuring in forward direction of forward, right, down (FRD) coordinate system or reference frame while enabling side-slip measurement in forward, right (FR) directions in FRD coordinate system or reference frame. Most sensors generally measure in three dimensions, and so are fully resolvable in their measurement space. Methods for boosting along the subspace according to Q-boosting algorithm and defined by the measurement matrix of the sensor may require extensive computational power. Accordingly, there is a need of improvement in error recovery mechanisms of Kalman filters equipped with outlier rejection mechanisms.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY

In one aspect, an autonomous vehicle including a Kalman filter error recovery system is disclosed. The Kalman filter error recovery system includes at least one processor and at least one memory storing instructions, which, when executed by the at least one processor, cause the Kalman filter error recovery system to perform operations including increasing eigenvalues of a covariance matrix to adjust probability distribution of a state vector error due to unmodelled process noise in measurements from one or more position sensors, and returning the state covariance to a diagonal state to perform a dynamic covariance reset

In another aspect, a method performed by a Kalman filter error recovery system of an autonomous vehicle is disclosed. The method includes increasing eigenvalues of a covariance matrix to adjust probability distribution of a state vector error due to unmodelled process noise in measurements from one or more position sensors and returning the state covariance to a diagonal state to perform a dynamic covariance reset.

In yet another aspect, a non-transitory computer-readable medium (CRM) is disclosed. The CRM embodies programmed instructions which, when executed by at least one processor of a Kalman filter error recovery system of an autonomous vehicle, cause the at least one processor to perform operations including increasing eigenvalues of a covariance matrix to adjust probability distribution of a state vector error due to unmodelled process noise in measurements from one or more position sensors and returning the state covariance to a diagonal state to perform a dynamic covariance reset.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic view of an autonomous truck.

FIG. 2 is a block diagram of a perception system.

FIG. 3 is an illustration of example vertical cross-sections of post-fit or Q-boosted position covariance ellipses plotted at the observation's locations of a planar map localizer during a GNSS outage;

FIG. 4A is an example depiction of a plausible pathological condition for the standard covariance reset heuristic;

FIG. 4B depicts an example evolution of eigenvalues of the 3×3 position state covariance block with the standard covariance reset algorithm;

FIG. 5 is a depiction of a case study showing the recovery of an error state EKF (ESEKF) after a typical drift during a prolonged GNSS outage.

FIG. 6 depicts a comparison of rejected GNSS samples after an outage, with the different recovery approaches shown in FIG. 4.

FIG. 7 is a block diagram of an example Kalman filter error recovery system, implemented in accordance with the teachings of this disclosure.

FIG. 8 is an example flow-chart of method operations performed by the Kalman filter recovery system shown in FIG. 7.

Corresponding reference characters indicate corresponding parts throughout the several views of the drawings. Although specific features of various examples may be shown in some drawings and not in others, this is for convenience only. Any feature of any drawing may be reference or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure. The following terms are used in the present disclosure as defined below.

An autonomous vehicle: An autonomous vehicle is a vehicle that is able to operate itself to perform various operations such as controlling or regulating acceleration, braking, steering wheel positioning, and so on, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that is able to perform some of the driving related operations such as keeping the vehicle in lane and/or parking the vehicle without human intervention. A semi-autonomous vehicle has an autonomy level of level-1, level-2, or level-3 recognized by NHTSA.

A non-autonomous vehicle: A non-autonomous vehicle is a vehicle that is neither an autonomous vehicle nor a semi-autonomous vehicle. A non-autonomous vehicle has an autonomy level of level-0 recognized by NHTSA.

The tuning of Kalman filters depends on being able to accurately model the process and observation and/or measurement noise. Process noise is a measure of state uncertainty that grows over time when no observations are available, for example, when the GNSS receiver does not receive signals from one or more satellites for a significant time duration. Observation noise can be thought of as the error distribution sampled by an individual sensor. Both process noise and/or observation noise may be modeled as zero-mean Gaussian distributions in a Kalman filter. It is typical to underestimate the true values of the covariances of the noise distributions. For one, estimating the true uncertainty is difficult, and error budgets may not account for all sources of error. Secondly, not all noise distributions are well modeled by a Gaussian model, and not all processes are linear, even if they work reasonably well with a Kalman Filter of the appropriate type. A good example of both cases that commonly appears in navigation is Global Navigation Satellite System (GNSS) sensors, which can have a non-Gaussian distribution, and typically report a lower signal covariance than its statistical protection level warrants.

Kalman filters are often equipped with an innovation-based outlier rejection mechanism. A typical mechanism is to reject innovations, or pre-fit residuals that have a Mahalanobis distance greater than some threshold amount (e.g., between 2.5 and 5). Rejection helps maintain that Gaussian assumption regarding observation error distributions at the cost of rejecting a very small number of valid observations. However, depending on the sources of error, outlier rejection can result in a state and covariance that force the rejection of valid observations. This is especially true when covariance estimates are over-optimistic.

Navigation filters that rely on a mixture of GNSS and odometry for positioning provide excellent illustrations of how the state estimation might enter a mode with unbounded error when error rejection is implemented. During periods of low or no GNSS availability, the global position estimate tends to drift from ground truth beyond the value reported by the state covariance due to accumulated errors in odometry and attitude estimation (i.e., dead reckoning). When reliable GNSS becomes available, good observations may be rejected after sufficiently long outages.

In some examples where outliers are known to lie on one side of the mean, as with GNSS multipath, one sided outlier rejection or gating may be sufficient. However, when outliers are not consistently distributed relative to the mean, multi-modal filters, such as multi-hypothesis tracking (i.e., filter bank), can be used to track multiple solutions with different initial conditions initialized at distinct times. Tracking allows for the evaluation of observations in the context of different solutions, which works well for situations like GNSS multipath, for example, but may come with significant additional computational cost. A simpler approach, as disclosed in embodiments herein, would be to reset or reinitialize the entire filter when a significant number of outliers has been detected or when a statistically implausible sequence of rejected observations has been detected.

In examples disclosed herein, the goal is to increase the state covariance to make up for unmodelled process noise, called Q-boosting. Simultaneously, in some examples, it may be desired to return the state covariance to a diagonal state to perform a dynamic covariance reset. For example, this may be performed by multiplying the diagonal (or diagonal elements) by some factor a while reducing the off-diagonal elements of the covariance matrix by a factor β=1/α for each encountered outlier. In examples disclosed herein, α and β are chosen to perform small changes during multiple update steps of the filter, so that only sequences of outliers cause significant exponential increase in the covariance, while individual outliers do not. In other words, α and β are chosen close to unity such that an increase in covariance is not significant from an individual outlier.

Standard Q-boosting can cause exponential growth of the covariance when the observations from a sensor do not span the entire space of the covariance, in addition to linear growth due to process noise. For example, in a filter with two sources of positions: GNSS and a source that provides one- or two-dimensional observations, such as a barometer or planar map localizer. During a period of unavailability of GNSS, rejected observations from the other position sensors will increase the covariance in all directions simultaneously if standard Q-boosting is used. However, good observations from a barometer may be able to collapse altitude covariance, good observations from a map localizer may be able to collapse lateral planar covariance. The covariance ellipsoid may continue to grow exponentially in all directions, but the dimensions not observable through a non-GNSS sensor may not collapse until good quality GNSS observations become available again.

In some examples, standard or conventional implementation of exponential Q-boosting may cause floating point overflow over a relatively short time during a GNSS outage with a small number of rejected observations, where linear growth due to the usual process noise may not have caused an overflow. A standard covariance reset heuristic can lead to an unexpected decrease in the eigenvalues of the covariance matrix, extending the period of rejection of good observations unnecessarily. Accordingly, boosting the covariance along dimensions that are unobservable by the sensor that triggered the boosting may not be reasonable.

In some examples, to develop a full simultaneous Q-boosting and covariance reset approach, the spectral theorem may be applied to the covariance matrix P.

$$\\ P ∈ \{ X ∈ {R}^{{}_{} nxn} \vert {X}^{{}_{} T} = X , X > 0 \}$$

The resulting eigen decomposition may include an orthogonal matrix of eigenvectors V∈SO(n) and a diagonal matrix of non-negative real eigenvalues ∧∈{diag (\vec{x})|\vec{x}∈Rⁿ}, such that P=V∧V^{T}. In some examples disclosed herein, as a member of SO(n), V may have a real skew-symmetric logarithm such that V=e^{k}, which may allow it to be raised to an arbitrary fractional power β∈R using Eqn. 1.

$$\\ \begin{matrix}{V}^{{}_{} β} = {e}^{{}_{} β log ( V )} = {e}^{{}_{} β K} & Eqn . 1\end{matrix}$$

The increase in the eigenvalues of P by some factor a and the simultaneously returning it to a diagonal form by a factor β may be computed using Eqn. 2 below. Typically, in some examples, by way of a non-limiting example, β∈{x∈R|0<x<1} and α∈{x∈R|x>1}.

$$\\ \begin{matrix}{P}_{reset} = α {V}^{β} ∧ {( {V}^{{}_{} β} )}^{T} & Eqn . 2\end{matrix}$$

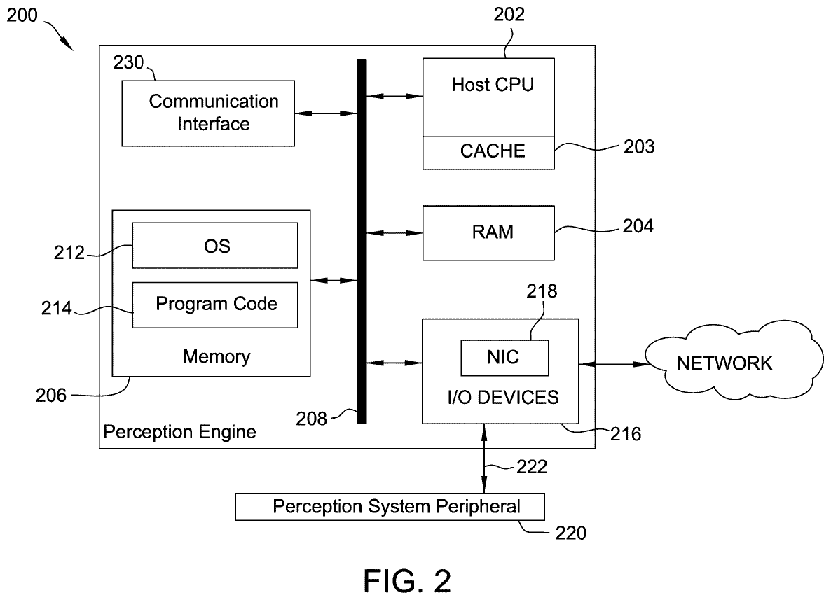

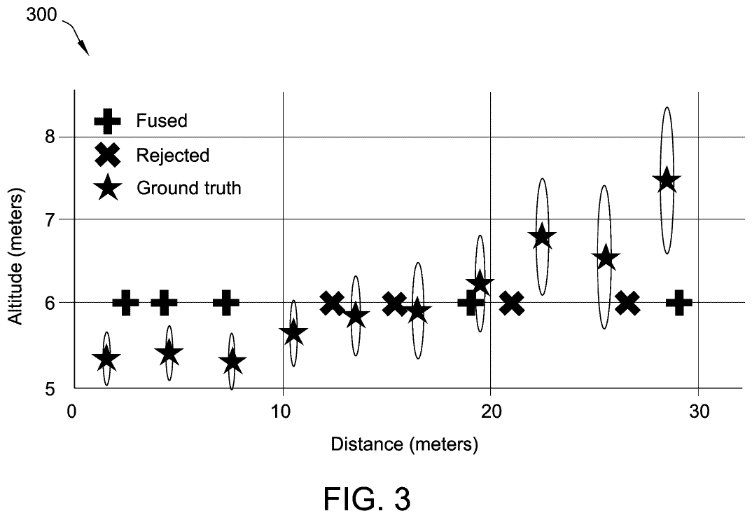

In some examples, the computation of V^{β} may be non-trivial for large covariance matrices. The simplified heuristic of increasing diagonal and decreasing off-diagonal elements of the state covariance works well for many cases but behaves unexpectedly under the example conditions shown in FIGS. 3A and/or 3B when the state covariance is non-spherical and not well aligned with the basis of the state vector. While the approach shown in Eqn. 2 is not susceptible to coordinate misalignment because V^{β} preserves eigenvalues, it may still suffer from issues with sensors whose observation Jacobian transposes do not span the full covariance space, as shown in the example of FIG. 2.

In some examples, to address the issue of incomplete row rank in observation Jacobians, a formulation of a directional Q-boosting operator may be derived. Using the sample example covariance matrix P as previously disclosed herein, as well as observation Jacobian H∈R^{m×n}, where m is the dimensionality of the sensor observation and n is the size of the state, P may be scaled by α∈R_{>0}, along the span of H⁺, the Moore-Penrose pseudo-inverse of H.

The Q-boosting performed in the example Eqn. 2 may be equivalent to adjusting of the probability distribution of the state vector error X. Specifically, in examples disclosed herein, Pᵣₑₛₑₜ may be interpreted in the context of linear transformation properties of a covariance matrix. Where the prior state vector distribution X may be characterized by P, the new distribution Xᵣₑₛₑₜ, in examples disclosed herein, may be characterized by Pᵣₑₛₑₜ according to Eqn. 3 shown below.

$$\\ \begin{matrix}{P}_{reset} = α {V}^{{}_{} β - 1} {P ( {V}^{{}_{} β - 1} )}^{T} & Eqn . 3\end{matrix}$$

In some examples, it may be required to boost X just along the subspace H⁺, rather than the span of P. In examples disclosed herein, for any error vector x drawn from X, there can be defined x=x_{∥}+x_{⊥}, where x_{∥} is the component of x within the subspace of H⁺, and x_{⊥} is the component in the nullspace. A projection operator J_{H}_{⁺} may be found which projects x onto the subspace of H⁺, namely:

$$\\ \begin{matrix}{x}_{‖} = {J}_{H} + x & Eqn . 4\end{matrix}$$

Based on J_{H}_{⁺}, a symmetric operator B can be built which boosts only x_{∥} by \sqrt{α}. Using this operator, the state covariance P can be boosted just along the subspace H⁺. The boosted covariance is obtained as P_{boosted}, =BPB. Additionally, a directional Q-boosting can be achieved, given by:

$$\\ \begin{matrix}{P}_{reset ′} = {BV}^{{}_{} {}_{} β} ∧ {( {V}^{{}_{} β} )}^{T} B & Eqn . 5\end{matrix}$$

Accordingly, as described herein, error recovery is required after a GNSS outage, since integrated odometry tends to drift away from the ground truth. The standard Q-boosting and covariance reset heuristic may cause a comparative and significant lag in convergence depending on the sampling frequency of the GNSS sensor. Examples disclosed herein mitigate this issue similarly with and without covariance reset. Since the boosting is exponential, the reset procedure does not make a significant impact on the filter and may generally be omitted.

One embodiment of the disclosed systems includes an autonomous vehicle including a variety of sensors, including at least one acoustic sensor, for perceiving the environment around the autonomous vehicle. The autonomous vehicle includes a perception system, including one or more processors and the variety of sensors, for detecting objects and obstacles in the environment and, in some cases, for determining their relative locations, velocities, and to make judgments about their future states or actions. Environmental perception includes object detection and understanding and may be based at least in part on data collected by acoustic sensors, image data collected, for example, by LiDAR sensors, radar, sonar, ultrasonic, or visual or RGB cameras, among other suitable active or passive sensors.

One embodiment of the disclosed systems includes an autonomous vehicle including one or more processors or processing systems that execute localization, i.e., a localization system. Localization is the process of determining the precise location of the autonomous vehicle using data from the perception system and data from other systems, such as a global navigation satellite system (GNSS) (e.g., a global positioning system (GPS) or an inertial measurement unit (IMU). The autonomous vehicle's position, both absolute and relative to other objects in the environment, is used for global and local mission planning, as well as for other auxiliary functions, such as determining expected weather conditions or other environmental considerations based on externally generated data.

One embodiment of the disclosed systems includes an autonomous vehicle including one or more processors or processing systems that execute behavior planning and control, i.e., a behavior planning and control system. Behavior planning and control includes planning and implementing one or more behavioral-based trajectories to operate an autonomous vehicle similar to a human driver-based operation. The behavior planning and control system uses inputs from the perception system or localization system to generate trajectories or other actions that may be selected to follow or enact as the autonomous vehicle travels. Trajectories may be generated based on known appropriate interaction with other static and dynamic objects in the environment, e.g., those indicated by law, custom, or safety. The behavior planning and control system may also generate local objectives including, for example, lane changes, obeying traffic signs, etc.

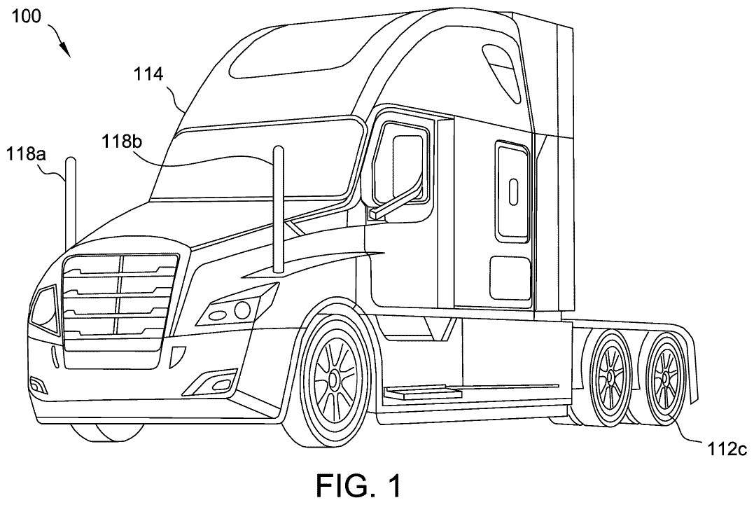

FIG. 1 illustrates a vehicle 100 which may include a truck that may further be conventionally connected to a single or tandem trailer to transport the trailers (not shown) to a desired location. The vehicle 100 includes a cabin 114 that can be supported by, and steered in, the required direction by front wheels 112a, 112b, and rear wheels 112c that are partially shown in FIG. 1. Wheels 112a, 112b are positioned by a steering system that includes a steering wheel and a steering column (not shown in FIG. 1). The steering wheel and the steering column may be located in the interior of cabin 114.

The vehicle 100 may be an autonomous vehicle, then the vehicle 100 may not have a steering wheel and a steering column to steer the vehicle 100. Rather, the vehicle 100 may be driven by a MCU (not shown) of the vehicle 100 based on data collected by a sensor network (not shown in FIG. 1) including one or more sensors.

FIG. 2 is a block diagram of an example perception system 200 for sensing an environment in which an autonomous vehicle is positioned. Perception system 200 includes a CPU 202 coupled to a cache memory 203, and further coupled to RAM 204 and memory 206 via a memory bus 208. Cache memory 203 and RAM 204 are configured to operate in combination with CPU 202. Memory 206 is a computer-readable memory (e.g., volatile, or non-volatile) that includes at least a memory section storing an OS 212 and a section storing program code 214. In alternative embodiments, one or more section of memory 206 may be omitted and the data stored remotely. For example, in certain embodiments, program code 214 may be stored remotely on a server or mass-storage device and made available over a network 232 to CPU 202.

Perception system 200 also includes I/O devices 216, which may include, for example, a communication interface such as a network interface controller (NIC) 218, or a peripheral interface for communicating with a perception system peripheral device 220 over a peripheral link 222. I/O devices 216 may include, for example, a GPU for operating a display peripheral over a display link, a serial channel controller or other suitable interface for controlling a sensor peripheral such as one or more acoustic sensors, a LiDAR sensor or a camera, or a CAN bus controller for communicating over a CAN bus.

FIG. 3 is an illustration of example vertical cross-sections 300 of post-fit or Q-boosted position covariance ellipses plotted at the observation's locations of a planar map localizer during a GNSS outage. In the example disclosed herein, ego-velocity is at 15 m/s in the +x-direction. Furthermore, in the disclosed example, sampling occurs at 5 Hz, with random observations being rejected. However, in other examples, the sampling frequency and ego-velocity may vary. A Q-boosting factor (e.g., of α=1.5) is used to emphasize unbounded growth of the uncertainty in the vertical direction while the lateral uncertainty settles to approximately the covariance of the map localizer observations with some small gain. FIG. 3 further shows an example of the covariance ellipsoid growing exponentially in directions not spanned by the non-GNSS sensor's observations subspace until good quality GNSS observations become available again (i.e., excessive growth).

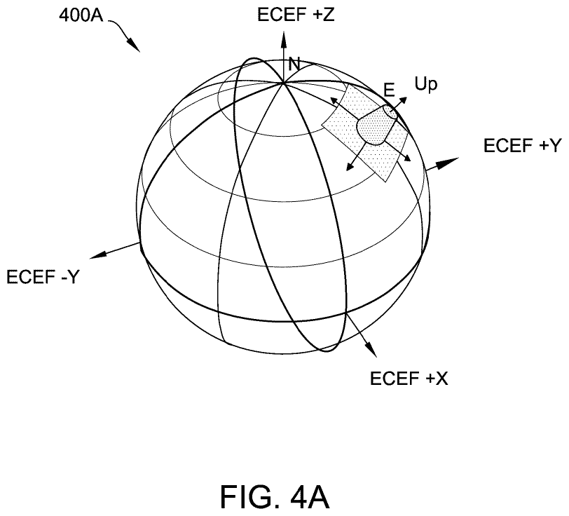

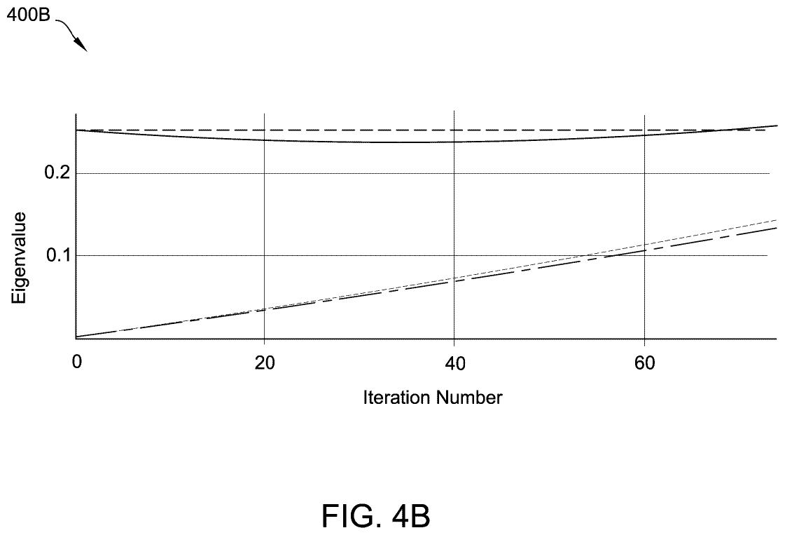

FIG. 4A illustrates a plausible pathological condition for the standard covariance reset heuristic, showing the position portion of a covariance ellipsoid on the surface of the Earth, aligned to local NED. The illustrated example of FIG. 4A is an example wherein the standard covariance reset heuristic, when utilized, can lead to an unexpected decrease in the eigenvalues of the covariance matrix, extending the period of rejection of good observations unnecessarily. In the example of FIG. 4A, the axes of the reference frame (e.g., for the Earth Centered Earth Fixed (ECEF)) do not align with the eigenspace of the sensor observations and state covariance (which are typically aligned to North-East-Down (NED) for GNSS observations).

FIG. 4B depicts an example evolution of eigenvalues of the 3×3 position state covariance block with the standard covariance reset algorithm. The illustrated example of FIG. 4B shows an unexpected dip in the largest eigenvalue caused by the deletion of information in off-diagonal elements, which is undesirable.

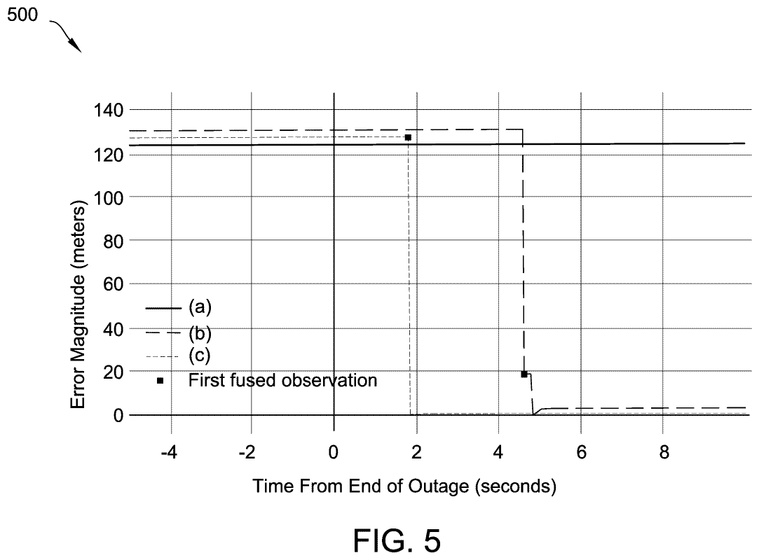

FIG. 5 is a depiction of a case study showing the recovery of an error-state EKF (ESEKF) after a typical drift during a prolonged GNSS outage. The illustrated example of FIG. 5 shows the behavior of the filter in four distinct scenarios: (a) no recovery mechanism, (b) standard Q-boosting and reset implementation (α=1.01, β=0.99), (c) the Q-boosting-only algorithm implemented in accordance with the teachings of this disclosure, and ground truth. In the example shown in FIG. 5, in the third scenario wherein the Q-boosting-only algorithm is implemented in accordance with the teachings of this disclosure, with α=1.01, the algorithm results are indistinguishable from the full algorithm with reset with α=1.01, β=0.99 at this scale.

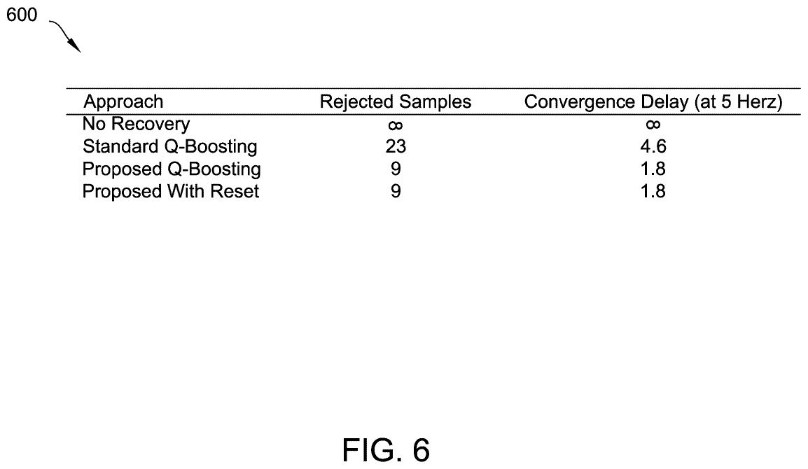

FIG. 6 is a table depiction 600 of comparison of rejected GNSS samples after an outage with the different recovery approaches shown in FIG. 5. As shown in the table depiction 600, the standard Q-boosting and covariance reset approaches cause a comparative lag in convergence as discussed herein with regards to FIG. 4A and FIG. 4B. Further, depending on the sampling frequency of the GNSS sensor, this lag can be significant. The sampling frequency of the GNSS sensor is 5 Hertz, for example, in the table depiction 600.

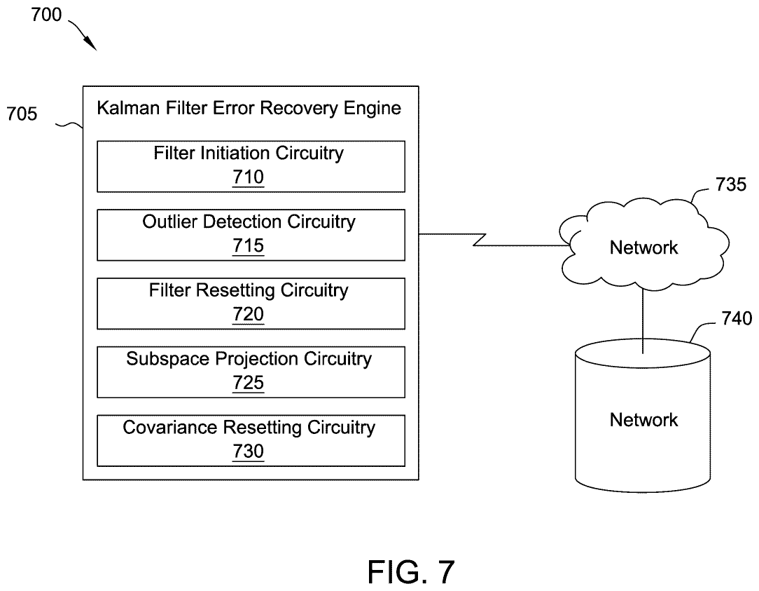

FIG. 7 is a block diagram of an example Kalman filter error recovery system 200 implemented in accordance with the teachings of this disclosure. The example Kalman filter error recovery system 200 includes, in examples disclosed herein, example filter initiation circuitry 710, example outlier detection circuitry 715, example filter resetting circuitry 720, example subspace projection circuitry 725, example covariance resetting circuitry 730, an example network 735, and example data 740. The example filter initiation circuitry 710 triggers the Kalman filter algorithm to run on a set of data (e.g., the example data 740). The outlier detection circuitry 715 then analyzes the results of the algorithm triggered by the filter initiation circuitry 710 and determines which datapoints are outliers in need of removal. The filter resetting circuitry 720 then, upon determining that the number of flagged outliers exceed a maximum acceptable threshold value, initiates the Kalman filter resetting process to mitigate the excessive number of identified outliers. The subspace projection circuitry 725 then obtains the orthogonal subspace spanned by the original subspace H⁺ from the decomposition of H⁺=QR. The covariance resetting circuitry 730 then, in some examples, performs a covariance reset by rotating P_{boosted}, by V^{β-1} to obtain the reset Kalman filter. In some examples, the Kalman filter error recovery engine 705 may be communicably coupled with the example data 740 via the example network 735.

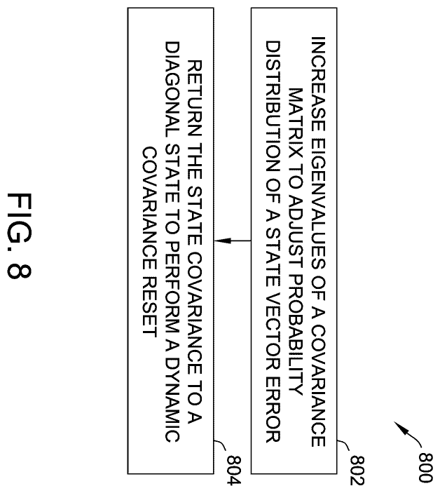

FIG. 8 is an example flow-chart 800 of method operations performed by the Kalman filter recovery system shown in FIG. 7. As shown in FIG. 8, eigenvalues of a covariance matrix may be increased 802 to adjust probability distribution of a state vector error due to unmodelled process noise, unmodelled measurement errors in measurements from one or more position sensors. In some embodiments, and by way of a non-limiting example, the probability distribution may be adjusted of a state vector error due to unmodelled control vectors or unmodelled source of uncertainty that affects estimate of the state uncertainty. Further, position sensors may be sensors of a global navigation satellite system (GNSS). In some embodiments, a spectral theorem may be applied to the covariance matrix to cause the covariance matrix to include an orthogonal matrix of eigenvectors V∈SO(n) and a diagonal matrix of non-negative real eigenvalues

$$\\ ∧ ∈ \{ diag ( {\to }_{x} ) \vert {\to }_{x} ∈ {R}^{{}_{} n} \} .$$

The method operations may include returning 804 the state covariance to a diagonal state to perform a dynamic covariance reset. By way of a non-limiting example, returning the state covariance to the diagonal state to perform the dynamic covariance reset may include multiplying diagonal elements by α factor a while reducing off-diagonal elements of a covariance matrix by a factor β for each encountered outlier. A value of the factor α is chosen to cause an exponential increase in covariance, and a value of the factor β is chosen to cause the covariance matrix to return to the diagonal state. Alternatively, or additionally, a value of the factor α and a value of the factor β may be chosen to cause no increase in covariance (or no significant increase in covariance) from an individual outlier, or to cause the covariance matrix to return to the diagonal state. The factor β may be an inverse (or a reciprocal) of the factor α. The state covariance may represent a Gaussian probability distribution, such as a Gaussian probability distribution centered on the state vector, as described herein.

An example technical effect of the methods, systems, and apparatus described herein includes at least one of: (a) improved performance of environmental sensing by autonomous vehicles; and (b) improved performance of autonomous vehicle maneuvering, routing, or operation more generally.

Some embodiments involve the use of one or more electronic processing or computing devices. As used herein, the terms “processor” and “computer” and related terms, e.g., “processing device,” “computing device,” and “controller” are not limited to just those integrated circuits referred to in the art as a computer, but broadly refers to a processors, a processing device, a controller, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory may include, but is not limited to, a non-transitory computer-readable medium, such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary embodiment” are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

We claim:

1. An autonomous vehicle, comprising:
a Kalman filter error recovery system including at least one processor and at least one memory storing instructions, which, when executed by the at least one processor, cause the Kalman filter error recovery system to perform operations comprising:
increasing eigenvalues of a covariance matrix to adjust probability distribution of a state vector error due to unmodelled process noise in measurements from one or more position sensors; and
returning the state covariance to a diagonal state to perform a dynamic covariance reset.

2. The autonomous vehicle of claim 1, wherein the operations further comprise applying a spectral theorem to the covariance matrix to cause the covariance matrix to include an orthogonal matrix of eigenvectors V∈SO(n) and a diagonal matrix of non-negative real eigenvalues
$$\\ ∧ ∈ \{ diag ( {\to }_{x} ) \vert {\to }_{x} ∈ {R}^{{}_{} n} \} .$$

3. The autonomous vehicle of claim 1, wherein the returning the state covariance to the diagonal state to perform the dynamic covariance reset comprises:
finding a sub-space of the covariance matrix spanned by the measurements and applying the factor α along the sub-space.

4. The autonomous vehicle of claim 3, wherein a value of the factor α is chosen to cause an exponential increase in covariance, and a value of the factor β is chosen to cause the covariance matrix to return to the diagonal state.

5. The autonomous vehicle of claim 3, wherein a value of the factor α and a value of the factor β are chosen close to unity such that an increase in covariance is not significant from an individual outlier and to cause the covariance matrix to return to the diagonal state.

6. The autonomous vehicle of claim 3, wherein the factor β in a reciprocal of the factor α.

7. The autonomous vehicle of claim 3, wherein the state covariance represents a Gaussian probability distribution.

8. A method performed by a Kalman filter error recovery system of an autonomous vehicle, the method comprising:
increasing eigenvalues of a covariance matrix to adjust probability distribution of a state vector error due to unmodelled process noise in measurements from one or more position sensors; and
returning the state covariance to a diagonal state to perform a dynamic covariance reset.

9. The method of claim 8, further comprising applying a spectral theorem to the covariance matrix to cause the covariance matrix to include an orthogonal matrix of eigenvectors V∈SO(n) and a diagonal matrix of non-negative real eigenvalues
$$\\ ∧ ∈ \{ diag ( {\to }_{x} ) \vert {\to }_{x} ∈ {R}^{{}_{} n} \} .$$

10. The method of claim 8, wherein the returning the state covariance to the diagonal state to perform the dynamic covariance reset comprises:
finding a sub-space of the covariance matrix spanned by the measurements and applying the factor α along the sub-space.

11. The method of claim 10, wherein a value of the factor α is chosen to cause an exponential increase in covariance, and a value of the factor β is chosen to cause the covariance matrix to return to the diagonal state.

12. The method of claim 10, wherein a value of the factor α and a value of the factor β are chosen close to unity such that an increase in covariance is not significant from an individual outlier and to cause the covariance matrix to return to the diagonal state.

13. The method of claim 10, wherein the factor β in a reciprocal of the factor α.

14. The method of claim 10, wherein the state covariance represents a Gaussian probability distribution.

15. A non-transitory computer-readable medium (CRM) embodying programmed instructions which, when executed by at least one processor of a Kalman filter error recovery system of an autonomous vehicle, cause the at least one processor to perform operations comprising:
increasing eigenvalues of a covariance matrix to adjust probability distribution of a state vector error due to unmodelled process noise in measurements from one or more position sensors; and
returning the state covariance to a diagonal state to perform a dynamic covariance reset.

16. The non-transitory CRM of claim 15, wherein the operations further comprising applying a spectral theorem to the covariance matrix to cause the covariance matrix to include an orthogonal matrix of eigenvectors V∈SO(n) and a diagonal matrix of non-negative real eigenvalues
$$\\ ∧ ∈ \{ diag ( {\to }_{x} ) \vert {\to }_{x} ∈ {R}^{{}_{} n} \} .$$

17. The non-transitory CRM of claim 15, wherein the returning the state covariance to the diagonal state to perform the dynamic covariance reset comprises:
finding a sub-space of the covariance matrix spanned by the measurements and applying the factor α along the sub-space.

18. The non-transitory CRM of claim 17, wherein a value of the factor α is chosen to cause an exponential increase in covariance, and a value of the factor β is chosen to cause the covariance matrix to return to the diagonal state.

19. The non-transitory CRM of claim 17, wherein the factor β in a reciprocal of the factor α.

20. The non-transitory CRM of claim 17, wherein the state covariance represents a Gaussian probability distribution.
